(19) United States
(12) Patent Application Publication
(10) Pub. No.: US 2007/0012951 A1
(43) Pub. Date: Jan. 18, 2007

(54) SEMICONDUCTOR DEVICE

(75) Inventors: Katsuhiro Kato, Tokyo (JP); Atsushi Nagayama, Tokyo (JP); Kenji Ichikawa, Tokyo (JP)

Correspondence Address: GLOBAL IP COUNSELORS, LLP, 1233 20TH STREET, NW, SUITE 700, WASHINGTON, DC, 20036-2680, US

(73) Assignee: Oki Electric Industry Co., Ltd., Tokyo (JP)

(21) Appl. No.: 11/425,706

(22) Filed: Jun. 22, 2006

(30) Foreign Application Priority Data
Jul. 15, 2005 (JP) 2005-207296

(51) Int. Cl. H01L 27/10

(52) U.S. Cl. 257/206

(57) ABSTRACT

An improved electrostatic discharge (ESD) protection structure that is suitable for use in a large-scale CMOS circuit fabrication technology is disclosed. When surge energy enters the first conductor during an ESD event, the surge current is conducted through the first contacts of the first MOS transistors, the second contacts of the first MOS transistors, the fourth conductor, and the third contacts of the second transistors. As each third contact is paired with each second contact, the surge current is conducted from a second contact to the paired third contact. Then, the surge current is conducted through the third contacts, fourth contacts, and the second conductor. In this operation, electric fields are generated in the direction of the first contacts, the second contacts, the fourth conductor, the third contacts, and the fourth contacts. Thus, the surge current is not conducted by way of the fifth conductor from a second contact to the other second contacts against the electric fields that are generated. Therefore, the surge current is only conducted from a second contact and the paired third contact. In other words, the surge current is dispersed, and is not conducted to a specific second contact.

### BACKGROUND OF THE INVENTION

1. Field of the Invention

The present invention generally relates to a semiconductor device, and more particularly relates to an electrostatic discharge (ESD) protection structure in a semiconductor device that comprises CMOS circuits.

2. Background Information

CMOS (Complementary Metal Oxide Semiconductor) circuits are extensively used in semiconductor integrated circuits (hereinafter referred to as a “semiconductor device”). A CMOS circuit has a pair of transistors comprising a PMOS transistor and a NMOS transistor. The PMOS transistor is connected to a power line (VDD level), and the NMOS transistor is connected to a ground line (GND level). The CMOS circuit is driven by the common gate voltage of the PMOS transistor and the NMOS transistor. Generally in a CMOS circuit, a NMOS transistor turns on (and a PMOS transistor turns off) when the gate voltage becomes VDD level, and a PMOS turns on (and a NMOS transistor turns off) when the gate voltage becomes GND level. Therefore, by commonly connecting the drains of the PMOS transistor and the NMOS transistor, the CMOS circuit functions as an inverter that transfers the opposite voltage level of the gate voltage to the following circuit. Logic circuits consisting of a plurality of CMOS circuits are designed on the basis of this inverter function. Hereinafter, a logic circuit consisting of CMOS circuits will be referred to as a “CMOS logic circuit”.

Meanwhile, a highly integrated semiconductor device is realized by locating gate electrodes on a shallow insulating layer that is on shallow impurity diffused regions. Therefore, a semiconductor device has a structure that is inherently vulnerable to ESD surge energy intruding from the outside. When ESD surge energy enters the VDD line in the CMOS circuit, the surge current is conducted from the sources of PMOS transistors, which are connected to VDD, to the drains of the PMOS transistors. Then, the surge current is conducted to the drains of NMOS transistors by way of a conductor that interconnects the drains of the PMOS transistors and the NMOS transistors. Finally, the surge current is conducted from the sources of the NMOS transistors to the ground line (GND).

In order to protect a CMOS logic circuit against an ESD surge event, a protection element is generally arranged in parallel with the CMOS logic circuit. A typical protection element is an NMOS protection transistor, with the drain thereof being connected to VDD, and the source, the gate, and the substrate (or well) thereof being connected to GND. A protection element conducts surge current through itself before the surge current is conducted through a CMOS logic circuit to break.

Meanwhile, a large-scale CMOS logic circuit is more vulnerable to an ESD surge event than a small-scale CMOS logic circuit, since the amount of surge current in a large-scale buffer circuit conducted at an ESD surge event is proportional to the quantity of CMOS circuits. Therefore, if a large amount of surge current is conducted through a specific PMOS or NMOS transistor in a large-scale CMOS logic circuit, the PN-junction of that specific transistor is prone to break.

This disadvantage during an ESD surge event in a large-scale CMOS logic circuit becomes even more apparent when a structure having silicide is employed for the circuit. Current drive performance is enhanced with silicide provided fully on source regions and drain regions in a CMOS logic circuit. However, the CMOS logic circuit is prone to receive more surge current than a protection circuit where normally silicide is not fully provided.

Japanese Patent Publication JP-A-2002-141416 discloses a CMOS buffer circuit having a plurality of PMOS transistors, and a NMOS transistor whose gate is wider than that of each PMOS transistor, in an attempt to enhance ESD immunity. However, when an ESD surge event occurs, the surge current can be conducted in a limited region of the source or drain of the NMOS transistor, thereby causing performance deterioration or breakage of the NMOS transistor.

In view of the above, it will be apparent to those skilled in the art from this disclosure that there exists a need for an improved semiconductor device comprised of large-scale CMOS circuits, and an electrostatic discharge (ESD) protection structure that enhances ESD immunity and is suitable for use in a large-scale CMOS circuit fabrication technology. This invention addresses this need in the art as well as other needs, which will become apparent to those skilled in the art from this disclosure.

### SUMMARY OF THE INVENTION

A semiconductor device according to the present invention may comprise: a first conductor (10); a second conductor disposed along the first conductor (20); a plurality of first MOS transistors (61) of a first conductivity type; a plurality of second MOS transistors (62) of a second conductivity type; and a third conductor (50) connecting the plurality of the second contacts with the plurality of the third contacts.

The plurality of first MOS transistors is disposed on the first conductor side between the first and second conductor. Each first MOS transistor has a first contact (103); a second contact (104); and a first control electrode (401) disposed between the first contact and the second contact. The plurality of second MOS transistors is disposed on the second conductor side between the first and second conductor. Each second MOS transistor has a third contact (204) paired with the second contact; a fourth contact (203); and a second control electrode (401) disposed between the third contact and the fourth contact. The plurality of first MOS transistors and the plurality of second MOS transistors form a plurality of CMOS circuits.

The third conductor has a plurality of fourth conductors (50-1 to 50-8) and a fifth conductor (50-0). Each of the plurality of fourth conductors (50-1 to 50-8) connects the second contact with the paired third contact. Fifth conductor (50-0) interconnects the plurality of fourth conductors.

When surge energy enters the first conductor during an ESD event, the surge current is conducted through the first contacts (103) of the first MOS transistors, the second contacts (104) of the first MOS transistors, the fourth conductor (50-1 to 50-8), and the third contacts (204) of the second transistors. As each third contact (204) is paired with each second contact (104), the surge current is conducted from a second contact (104) to the paired third contact (204). Then, the surge current is conducted through the third contacts (204), fourth contacts (203), and the second conductor (20). In this operation, electric fields are generated in the direction of the first contacts (103), the second contacts (104), the fourth conductor (50-1 to 50-8), the third contacts (204), and the fourth contacts (203). Thus, the surge current is not conducted by way of the fifth conductor (50-0) from a second contact (104) to the other second contacts (104) against the electric fields that are generated.

Therefore, the surge current is only conducted from a second contact (104) and the paired third contact (204). In other words, the surge current is dispersed, and is not conducted to a specific second contact.

These and other objects, features, aspects and advantages of the present invention will become apparent to those skilled in the art from the following detailed description, which, taken in conjunction with the annexed drawings, discloses a preferred embodiment of the present invention.

### BRIEF DESCRIPTION OF THE DRAWINGS

Referring now to the attached drawings which form a part of this original disclosure:

FIG. 1A is a plan view of a semiconductor device according to a first embodiment of the present invention;

FIG. 1B is a diagram for explaining the regions of the semiconductor device according to the first embodiment;

FIG. 1C is a diagram for explaining ESD (electrostatic discharge) current paths in the semiconductor device according to the first embodiment;

FIG. 1D is a diagram for describing a preferable location of a conductor connecting drain with respect to drain contacts;

FIG. 1E is a diagram for describing a preferable location of a conductor connecting drain with respect to drain contacts;

FIG. 2A is a plan view of a semiconductor device according to a second embodiment of the present invention;

FIG. 2B is a diagram for explaining the regions of the semiconductor device according to the second embodiment;

FIG. 2C is a diagram for explaining the ESD current paths in the semiconductor according to the second embodiment;

FIG. 3A is a plan view of a semiconductor device according to a third embodiment of the present invention;

FIG. 3B is a diagram for explaining the regions of the semiconductor device according to the third embodiment;

FIG. 3C is a diagram for explaining the ESD current paths in the semiconductor device according to the third embodiment;

FIG. 4A is a plan view of a semiconductor device according to a fourth embodiment of the present invention;

FIG. 4B is a diagram for explaining the regions of the semiconductor device according to the fourth embodiment; and

FIG. 4C is a diagram for explaining the ESD current paths in the semiconductor according to the fourth embodiment.

### DETAILED DESCRIPTION OF THE PREFERRED EMBODIMENTS

Selected embodiments of the present invention will now be explained with reference to the drawings. It will be apparent to those skilled in the art from this disclosure that the following descriptions of the embodiments of the present invention are provided for illustration only and not for the purpose of limiting the invention as defined by the appended claims and their equivalents.

### First Embodiment

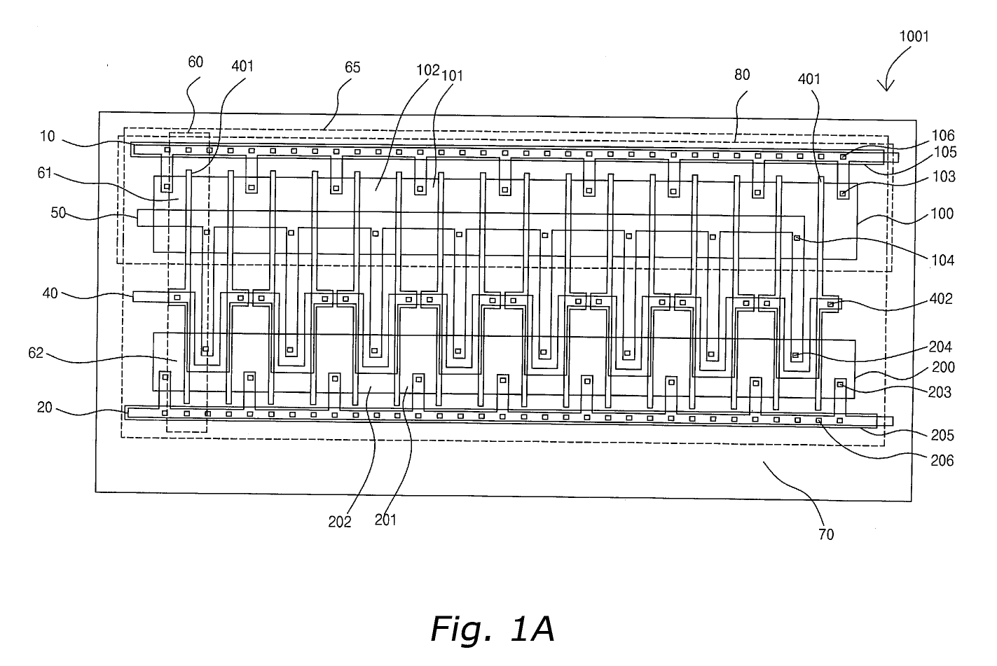

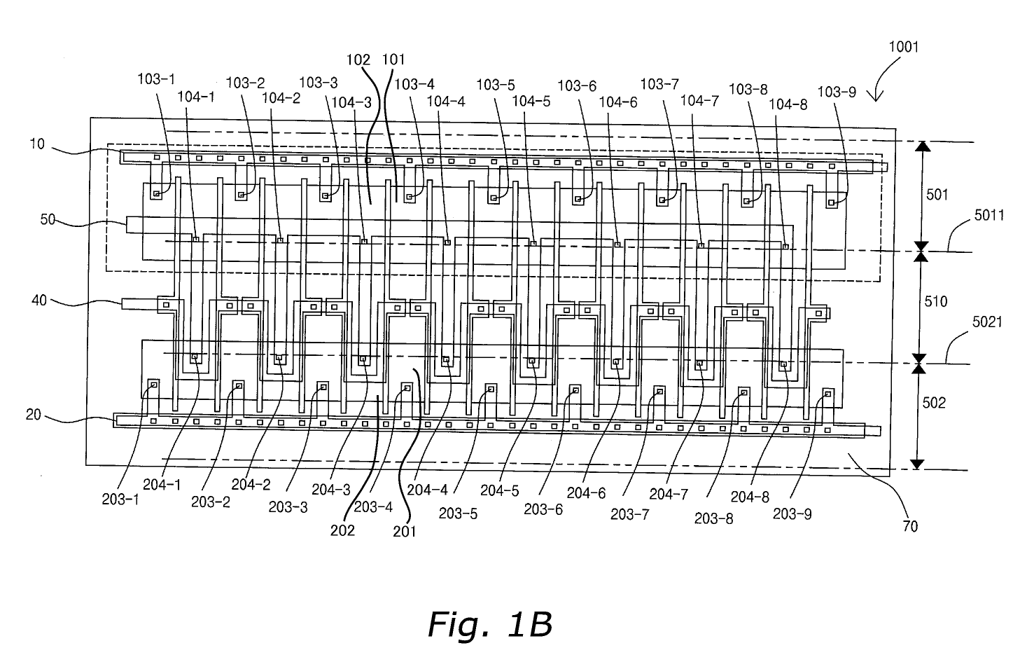

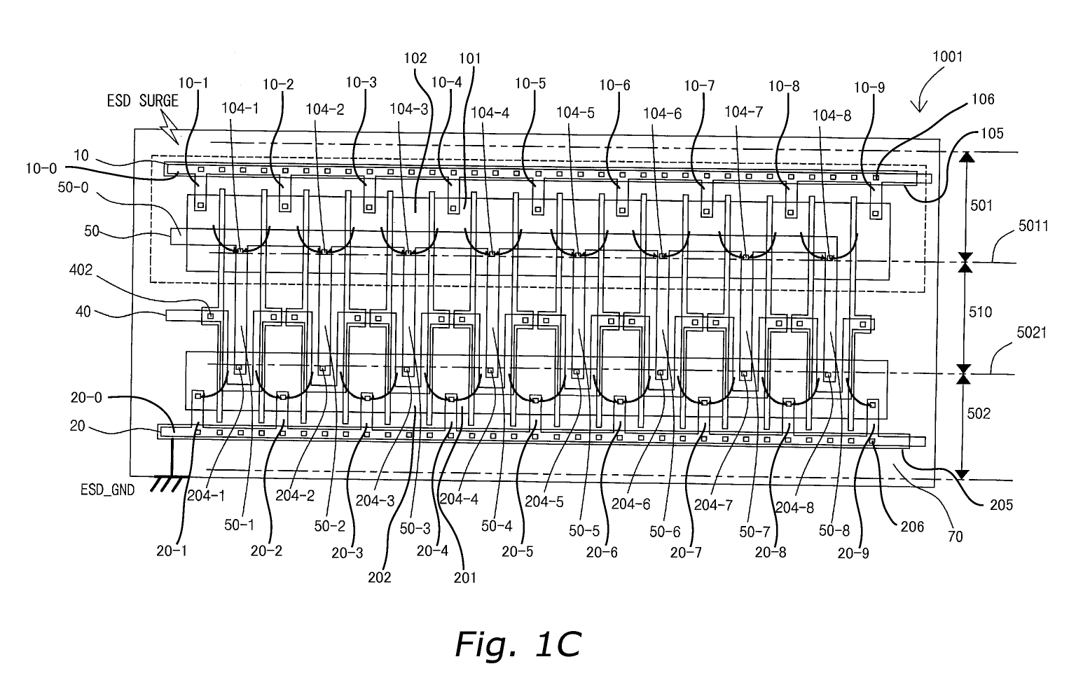

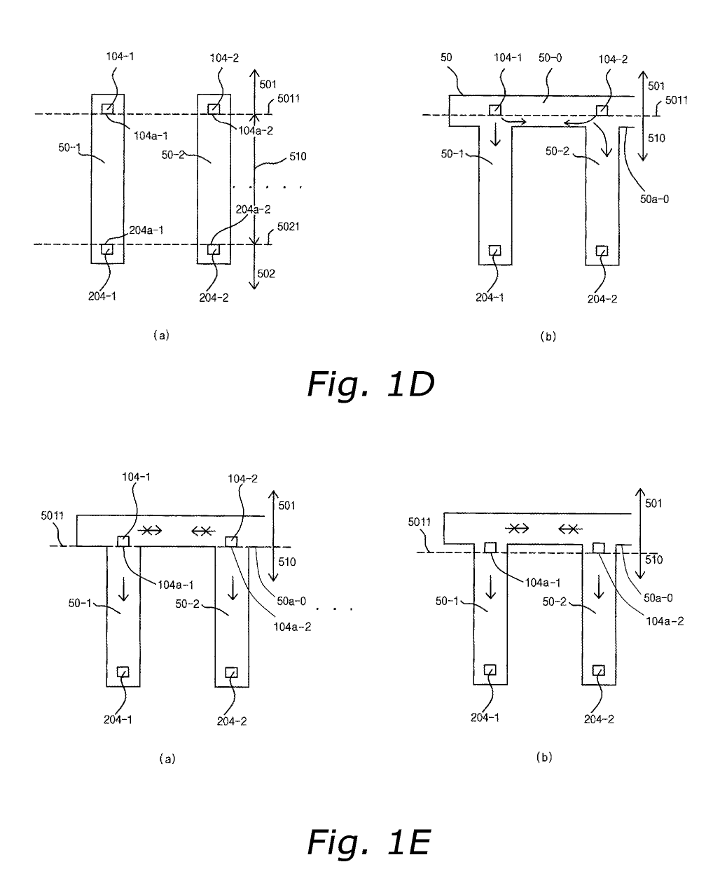

FIG. 1A is a plan view of a semiconductor device 1001 according to a first preferred embodiment of the present invention. FIG. 1B is a diagram for explaining each region of the semiconductor device 1001. FIG. 1C is a diagram for explaining the ESD (electrostatic discharge) current paths in the semiconductor device 1001.

Referring to FIG. 1A, sixteen PMOS transistors 61 are formed in a P-type impurity region 100 in the present embodiment, while sixteen NMOS transistors 62 are formed in an N-type impurity region 200. A pair comprised of a PMOS transistor 61 and an NMOS transistor 62 forms a CMOS circuit 60. Sixteen CMOS circuits 60 form a large-scale CMOS circuit 65. For example, the large-scale CMOS circuit 65 may be a buffer circuit following an inverter circuit (not shown in the figure).

An N-well 80 is disposed on a surface of P-type substrate 70. P-type impurity region 100 and region 105 are disposed within N-well 80. N-type impurity region 200 and region 205 are both disposed on a portion of the surface of P-type substrate 70 on which N-well 80 is not disposed.

N-well 80 is an impurity diffused region formed by doping and diffusing an N-type impurity such as Arsenic (As), Phosphorus (P) on the surface of P-type substrate 70. N-well 80 is a region for forming the PMOS transistors 61.

P-type impurity region 100 is a region where a plurality of PMOS transistors 61 is formed. P-type impurity region 100 is an impurity diffused region formed by implanting and diffusing a P-type impurity such as Boron (B) within N-well 80. P-type impurity region 100 is sectioned by a plurality of gate electrodes 401 (see below) into: source regions 101 of PMOS transistors 61; drain regions 102 of PMOS transistors 61; and a region that underlies gate electrodes 401 and is disposed between source region 101 and drain region 102 so as to act as a channel layer during operation. Source regions 101 and drain regions 102 are alternately disposed on both sides of each gate electrode 401.

Referring to FIG. 1B, source contacts 103 (103-1 to 103-9) are provided on each source region 101 on the conductor 10 side (VDD). Drain contacts 104 (104-1 to 104-8) are provided on each drain region 102 on the conductor 20 side (GND).

In the present embodiment, as shown in FIG. 1A, the source regions 101 and drain regions 102 sectioned by gate electrodes 401 are alternately arranged. A total of nine source regions 101 and eight drain regions 102 are arranged. Each source region 101 and drain region 102 commonly form adjacent PMOS transistors, thereby forming a total of sixteen PMOS transistors. For example, referring to FIG. 1B, drain region 102 including drain contact 104-1 commonly forms a transistor having source region 101 including source contact 103-1, and a transistor having region 101 including source contact 103-2. Source region 101 including source contact 103-2 commonly forms a transistor having drain region 102 including drain contact 104-1, and a transistor having drain region 102 including drain contact 104-2. Source region 101 including source contact 103-1, and drain region 102 including drain contact 104-1, form a PMOS transistor 61. Drain region 102 including drain contact 104-1, and source region 101 including source contact 103-2, form a PMOS transistor 61. Source region 101 including source contact 103-2, and drain region 102 including drain contact 104-2, form a PMOS transistor 61. In this way, nine source regions 101 and eight drain regions 102 of P-type impurity region 100 form a total of sixteen PMOS transistors 61. P-type impurity region 100 extends in the direction in which the plurality of PMOS transistors 61 is arranged.

Region 105 is an impurity diffused region where an N-type impurity such as Arsenic (As) or Phosphorus (P) is heavily doped and diffused, and retains the electric potential of conductor 10 at that of N-well 80. Region 105 is provided in a band shape in the direction in which P-type impurity region 100 extends. In other words, region 105 is provided in the direction in which a plurality of PMOS transistors 61 is arranged. A plurality of contacts 106 are located on region 105 in the direction in which a plurality of PMOS transistors 61 is arranged. In the present embodiment, the quantity of contacts 106 is substantially equal to the sum of the quantities of source contacts 103, drain contacts 104, and gate electrodes 401. However, any quantity of contacts 106 could be provided in order to retain the electric potential of conductor 10 at that of the N-well 80.

N-type impurity region 200 is a region that forms a plurality of NMOS transistors 62. N-type impurity region 200 is an impurity diffused region where an N-type impurity such as Arsenic (As) or Phosphorus (P) is heavily doped and diffused in a region other than N-well 80 on the surface of the P-type substrate 70. N-type impurity region 200 is sectioned by a plurality of gate electrodes 401 into: source regions 201 of NMOS transistors 62; drain regions 202 of NMOS transistors 62; and a region that underlies gate electrodes 401 and is disposed between source region 201 and drain region 202 so as to act as a channel layer during operation. Source region 201 and drain region 202 are alternately arranged on both sides of each gate electrode 401.

Referring to FIG. 1B, source contacts 203 (203-1 to 203-9) are provided on source regions 201. Drain contacts 204 (204-1 to 204-8) are provided on drain regions 202.

In the present embodiment, as shown in FIG. 1A, the source regions 201 and drain regions 202 sectioned by gate electrodes 401 are alternately arranged. A total of nine source regions 201 and eight drain regions 202 are arranged. Each of source region 201 and drain region 202 commonly form adjacent NMOS transistors, thereby forming a total of sixteen NMOS transistors. For example, referring to FIG. 1B, drain region 202 including drain contact 204-1 commonly forms a transistor having source region 201 including source contact 203-1, and a transistor having region 201 including source contact 203-2. Source region 201 including source contact 203-2 commonly forms a transistor having drain region 202 including drain contact 204-1, and a transistor having drain region 202 including drain contact 204-2. Source region 201 including source contact 203-1, and drain region 202 including drain contact 204-1, form a NMOS transistor 62. Drain region 202 including drain contact 204-1, and source region 201 including source contact 203-2, form a NMOS transistor 62. Source region 201 including source contact 203-2, and drain region 202 including drain contact 204-2, form a NMOS transistor 62. In this way, nine source regions 201 and eight drain regions 202 of N-type impurity region 200 form a total of sixteen NMOS transistors 62. N-type impurity region 200 extends in the direction in which a plurality of NMOS transistors 62 is arranged.

Region 205 is an impurity diffused region where a P-type impurity such as Boron (B) is heavily doped and diffused, and retains the electric potential of conductor 20 at that of P-type substrate 70 (substrate voltage). Region 205 is band shaped, and provided in the direction in which N-type impurity region 200 extends. In other words, region 205 is provided in the direction in which a plurality of NMOS transistors 62 is arranged. A plurality of contacts 206 are located on region 205 in the direction in which a plurality of NMOS transistors 62 is arranged. In the present embodiment, the quantity of contacts 206 is substantially equal to the sum of the quantities of source contacts 203, drain contacts 204, and gate electrodes 401. However, any quantity of contacts 206 could be provided in order to retain the electric potential of conductor 20 at that of the substrate.

As shown in FIG. 1B, region 501, region 510, and region 502 are defined in semiconductor device 1001 according to the present embodiment for explanatory convenience.

Referring to FIG. 1B and FIG. 1D, region 501 is defined to be a region extending from edges 104a (104a-1 to 104a-8) (see FIG. 1D) on the conductor 20 side of drain contacts 104 (104-1 to 104-8) toward conductor 10, which includes a region that overlaps with drain contacts 104 (104-1 to 104-8). Region 501 includes boundary 5011 that interconnects edges 104a.

Region 510 is defined to be a region extending between edges 104a on the conductor 20 side of drain contacts 104 (104-1 to 104-8) and edges 204a on the conductor 10 side of drain contacts 204 (204-1 to 204-8), which excludes the region that overlaps with drain contacts 104 (104-1 to 104-8) and 204 (204-1 to 204-8). Region 510 excludes boundary 5011 and boundary 5021 that interconnect edges 204a.

Region 502 is defined to be a region extending from edges 204a (204a-1 to 204a-8) (see FIG. 1D) on the conductor 10 side of drain contacts 204 (204-1 to 204-8) toward conductor 20, which includes the region that overlaps with drain contacts 204 (204-1 to 204-8). Region 501 includes boundary 5021.

Gate electrodes 401 are disposed on P-type impurity region 100 and N-type impurity region 200 in the orthogonal direction in which P-type impurity region 100 and N-type impurity region 200 extend. In the present embodiment, sixteen gate electrodes 401 are disposed. Gate electrodes 401 overlie P-type substrate 70 by way of gate dielectrics (not shown in the figure). Gate electrodes 401 in the present embodiment are commonly provided to form PMOS transistors 61 and NMOS transistors 62. However, gate electrodes of PMOS transistors 61 and gate electrodes of NMOS transistors 62 may be disposed separately and interconnected by a conductor.

Gate electrodes 401 sections P-type impurity region 100 into a plurality of source regions 101 and a plurality of drain regions 102. In the present embodiment, nine source regions 101 and eight drain regions 102 sectioned in P-type impurity region 100 are alternately arranged. Gate electrodes 401 sections N-type impurity region 200 into a plurality of source regions 201 and a plurality of drain regions 202. In the present embodiment, nine source regions 201 and eight drain regions 202 sectioned in N-type impurity region 200 are alternately arranged On region 510 extending between P-type impurity region 100 and N-type impurity region 200, each gate electrode 401 has a projection portion along the direction in which P-type impurity region 100 and N-type impurity region 200 extends. Gate contact 402 is provided on the projection portion of each gate electrode 401.

First interlayer dielectric (not shown in the figure) overlies the surface of P-type substrate 70. First interlayer dielectric covers P-type impurity region 100, N-type impurity region 200, region 105, region 205, and gate electrodes 401.

A first metal conductor layer overlies first interlayer dielectric. The first metal conductor layer includes conductor 10, conductor 20, conductor 40, and conductor 50, and is formed of aluminum (Al), or a laminate of aluminum (Al) and titan nitride (TiN) or the like.

A conductor 10 receives power voltage VDD when semiconductor device 1001 is in operation. Region 105 receives power voltage VDD when semiconductor device 1001 is in operation, and retains the electric potential of conductor 10 at that of VDD by way of a plurality of contacts 106. Referring to FIG. 1C, conductor 10 is disposed in the direction in which region 105 extends. Conductor 10 is comprised of a conductor 10-0 and a plurality of conductors 10-1 to 10-9. Conductor 10-0 overlies region 105 by way of first interlayer dielectric. Conductors 10-1 to 10-9 appear like fingers in FIG. 1A, extending from the conductor 10-0 and overlying a plurality of source regions 101 of PMOS transistors 61. The conductor 10-0 is connected to region 105 by way of a plurality of contacts 106. Contacts 106 are located within contact holes provided in first interlayer dielectric. Each front end of a plurality of the conductors 10-1 to 10-9 overlies each source region 101 by way of first interlayer dielectric. Each front end of a plurality of the conductors 10-1 to 10-9 extends to the edge of source regions 101 on the region 105 side. Each front end of a plurality of the conductors 10-1 to 10-9 is connected to each source region 101 by way of source contacts 103 (103-1 to 103-9). Source contacts 103 (103-1 to 103-9) are located within contact holes provided in the first interlayer dielectric.

Conductor 20 receives ground voltage GND when semiconductor device 1001 is in operation. Region 205 receives ground voltage GND when semiconductor device 1001 is in operation, and retains the electric potential of conductor 20 at that of GND by way of a plurality of contacts 206. Referring to FIG. 1C, conductor 20 is disposed in the direction in which region 205 extends. Conductor 20 is comprised of a conductor 20-0 and a plurality of conductors 20-1 to 20-9. Conductor 20-0 overlies region 205 by way of the first interlayer dielectric. Conductors 20-1 to 20-9 appear as a whole like fingers in FIG. 1A, extending from the conductor 20-0 and overlying a plurality of source regions 201 of NMOS transistors 62. The conductor 20-0 is connected to region 205 by way of a plurality of contacts 206. Contacts 206 are located within contact holes provided in the first interlayer dielectric. Each front end of a plurality of the conductors 20-1 to 20-9 overlies each source region 201 by way of the first interlayer dielectric. Each front end of a plurality of the conductors 20-1 to 20-9 extends to the edge of source region 201 on the region 205 side. Each front end of a plurality of the conductors 20-1 to 20-9 is connected to each source region 201 by way of source contacts 203 (203-1 to 203-9). Source contacts 203 (203-1 to 203-9) are located within contact holes provided in the first interlayer dielectric.

As shown in FIG. 1C, conductor 50 is disposed so as to cross over gate electrodes 401 that overlie P-type impurity region 100. Conductor 50 is comprised of conductor 50-0 overlying first interlayer dielectric and a plurality of conductors 50-1 to 50-8 extending from conductor 50-0 toward a plurality of drain regions 202 of N-type impurity region 200. Each of the conductors 50-1 to 50-8 extends to drain region 202 of NMOS transistor 62. Conductor 50 is a portion of an output section that outputs a voltage from each CMOS circuit 60 to the following circuit.

Each of the conductors 50-1 to 50-8 is connected, at its frond end, to each drain region 202 of NMOS transistors 62 by way of drain contacts 204 (204-1 to 204-8). Each of the conductors 50-1 to 50-8 is connected, at the other end (at the base of the “finger”), to each drain region 102 of PMOS transistors 61 by way of drain contacts 104 (104-1 to 104-8). Drain contacts 104 and drain contacts 204 are located within contact holes provided in the first interlayer dielectric.

A plurality of contact holes connecting drain region 202 are provided within the first interlayer dielectric on the conductor 20 side of the edges of conductors 50-1 to 50-8. Drain contact 204 provided for each contact hole allows the edge of each conductor 50-1 to 50-8 to connect to the corresponding drain region 202.

A plurality of contact holes connecting drain regions 102 are provided within the first interlayer dielectric on the conductor 10 side of the base of conductors 50-1 to 50-8. Drain contact 104 provided for each contact hole allows the edge of each conductor 50-1 to 50-8 to connect to the corresponding drain region 102.

More specifically, each of the conductors 50-1 to 50-8 respectively connects drain contact 104 with the paired drain contact 204 in a PMOS transistor 61 and NMOS transistor 62 pair.

Conductor 50-0 is located in region 501, and interconnects conductors 50-1 to 50-8. Conductor 50 connects drain contacts 104 for PMOS transistors 61 and drain contacts 204 for NMOS transistors 62 one-to-one by way of conductors 50-1 to 50-8. Conductors 50-1 to 50-8 are connected to each other by way of conductor 50-0 in region 501.

Referring now to FIG. 1C, conductor 40 interconnecting the gate contacts 402 is disposed on the conductor 20 side of conductor 50. Conductor 40 is formed in a series of U-shapes for each of the conductors 50-1 to 50-8 so as to detour each of the conductors 50-1 to 50-8. Conductor 40 is connected to gate electrodes 401 by way of gate contacts 402. Each gate contact 402 is located within a contact hole formed in the first interlayer dielectric that lies between gate electrodes 401 and conductor 40.

The operation of semiconductor device 1001 will now be described. In semiconductor device 1001 comprised of a large-scale CMOS circuit having sixteen CMOS circuits 60, conductor 40 is connected to the drain of a preceding inverter circuit. In operation of semiconductor device 1001, an output signal of the inverter circuit is inputted from its drain to each CMOS circuit 60. Then, in response to the logic of the output signal, each CMOS circuit 60 outputs a high-level or a low-level signal from conductor 50.

In this semiconductor device 1001, conductor 10 and conductor 20 can be open when carrying the device, thereby causing the circuits to electrically float. Thus, if a positive surge enters conductor 10 during an ESD surge event, the surge current will be conducted to drain contacts 104 (104-1 to 104-8) by way of source contacts (103-1 to 103-9), source regions 101, and drain regions 102 of PMOS transistors 61. The surge current conducted to each of drain contacts 104 (104-1 to 104-8) is then conducted to one of the drain contacts 204 (204-1 to 204-8) of the NMOS transistors 62 by way of one of the corresponding conductors 50-1 to 50-8 of conductor 50. For example, the surge current is conducted from drain contact 104-1 to the paired drain contact 204-1 by way of conductor 50-1. Similarly, the surge current is conducted from drain contact 104-2 to the paired drain contact 204-2 by way of conductor 50-2.

Accordingly, surge current conducted to drain contacts 104 (104-1 to 104-8) is not conducted to one specific drain contact 204, and is dispersed to NMOS transistors 62 by way of drain contacts 204 (204-1 to 204-8).

This semiconductor device is operated in this way, because, when surge current is conducted to conductor 10, electric fields are generated from drain contacts 104-1 to 104-8 to the paired drain contacts 204-1 to 204-8 one-to-one. For example, an electric field is generated from drain contacts 104-1 to the paired drain contact 204-1, while an electric field is generated from drain contacts 104-2 to the paired drain contacts 204-2. Thus, the surge current will not be conducted from any drain contact 104 to the adjacent drain contact 104 by way of conductor 50-0, since the direction of the current would be against the opposite direction of the electric fields that are generated.

For example, surge current is not conducted from drain contact 104-1 to drain contact 204-2 by way of drain contact 104-2, since the direction of the surge current is against a direction of an electric field generated from drain contact 104-1 to drain contact 204-1.

Therefore, surge current conducted to drain contacts 104-1 to 104-8 is conducted to the paired drain contacts 204-1 to 204-8 one-to-one. In other words, surge current conducted to each PMOS transistor 61 is conducted to the paired NMOS transistor 62. As a result, surge current conducted to each of PMOS transistors 61 is not conducted to one specific NMOS transistor 62, and is dispersed to all NMOS transistors 62.

In this way, with the semiconductor device according to the present embodiment, each of the CMOS circuits that form a large-scale CMOS circuit can be prevented from performance deterioration or breakage during an ESD surge event. Accordingly, inverter circuits and buffer circuits in the semiconductor device will have high ESD immunity. This semiconductor device will be suitable particularly for a large-scale CMOS logic circuit in which source regions and drain regions are clad with silicide film.

The semiconductor device according to the present embodiment may be manufactured through a conventional CMOS manufacturing process with a slight change in conductor 50. No increase of area for the CMOS circuits is involved, as unoccupied regions for conductors may be used to implement the change in conductor 50.

Referring now to FIG. 1D and FIG. 1E, a preferable modification will be described below. FIG. 1D and FIG. 1E are diagrams for describing a preferable location of conductor 50 with respect to the location of the drain contacts 104 (104-1 to 104-8). In FIG. 1D, conductor 50-0 is omitted for the sake of brevity.

FIG. 1D(b) shows the relationship between conductor 50 and drain contacts 104, when edge 50a-0 of conductor 50-0 is located on the NMOS transistor 62 side of boundary 5011 (see FIG. 1D(a)) that connects edges 104a of contacts 104. FIG. 1D illustrates an undesirable location of conductor 50. In this configuration, a portion of conductor 50-0 is on the NMOS transistor 62 side of drain contacts 104-1 to 104-8. Since electric fields are generated in this partial region directing from drain contact 104-1 to drain contacts 204-1 and 204-2, it is possible that surge current will be conducted from drain contact 104-1 to both drain contacts 204-1 and 204-2. Thus, with the configuration shown in FIG. 1D(b), there is a possibility that surge current is conducted, by way of conductor 50-0, to one of drain contacts 204-1 to 204-8 from any of drain contacts 104-1 to 104-8 other than the paired drain contact.

Therefore, in order to prevent surge current from being conducted from drain contacts 104-1 to 104-8 to adjacent drain contacts by way of conductor 50-0, it is preferable that the line of edges 50a-0 of conductor 50-0 match boundary 5011 (see FIG. 1E(a)), or be located on the conductor 10 side of boundary 5011 (see FIG. 1E(b)).

When conductor 50 is located as shown in FIG. 1E(a) or FIG. 1E(b), surge current will only be conducted from each of the drain contacts 104-1 to 104-8 to the corresponding drain contacts 204-1 to 204-8 along an electric field generated therebetween. In other words, the surge current is not conducted by way of conductor 50-0. This is because, as shown in the configuration of FIG. 1E(a) or FIG. 1E(b), conductor 50-0 does not have a portion thereof on the NMOS transistor 62 side of drain contacts 104-1 to 104-8.

In addition, as another modification, conductor 50-0 of conductor 50 may be located in region 502 on the drain contacts 204 side. This configuration prevents surge current from conductor 20 from being conducted to one specific PMOS transistor 61.

As a preferable modification, conductor 50-0 may be provided not only for PMOS transistors 61 in region 501, but also for NMOS transistors 62 in region 502. To realize this configuration, conductor 40 and conductor 50 may be disposed on separate conductor layers. Or alternatively, conductors 50-1 to 50-8 may be disposed on the first metal conductor layer, while conductors 50-0 and conductor 40 are disposed on the second metal conductor layer. Or alternatively, conductors 50-1 to 50-8 and conductor 40 may be disposed on the first metal conductor layer, while conductor 50-0 is disposed on the second metal conductor layer.

As a preferable modification, conductors 50-1 to 50-8 may be disposed on the first metal conductor layer, while conductor 50-0 may be disposed on the second metal conductor layer that overlies first metal conductor layer. Namely, conductor 50-0 and conductors 50-1 to 50-8 may not necessarily be disposed in an identical metal conductor layer. When conductor 50-0 is disposed in the second metal conductor layer, conductor 50-0 may be disposed on second interlayer dielectric layer that overlies the first metal conductor layer, and then conductor 50-0 and conductors 50-1 to 50-8 may be connected by way of a contact located through the second interlayer dielectric. In this configuration, since conductor 50-0 and conductor 40 are disposed in separate layers, flexibility in locating conductor 40 will be increased.

As a preferable modification, conductor 50 may be disposed in a first metal conductor layer, while conductor 40 may be disposed in a second metal conductor layer that overlies the first metal conductor layer. Namely, conductor 50 and conductor 40 may not necessarily be disposed in an identical metal conductor layer. When conductor 40 is disposed in the second metal conductor layer, conductor 40 may be disposed on second interlayer dielectric layer that covers the first metal conductor layer. In order to electrically connect conductor 40 with gate electrodes 401, the conductor 40 in the second metal conductor layer is connected to conductor 45 (not shown) in first metal conductor layer, and then the conductor 45 is connected to gate electrodes 401. In this configuration, the first metal conductor layer (conductor 45) is preferably formed so as to be small in size enough to dispose gate contact 402. Since conductor 40 and conductor 45 are disposed in separate layers in this configuration, flexibility in locating conductor 40 will be increased.

### Second Embodiment

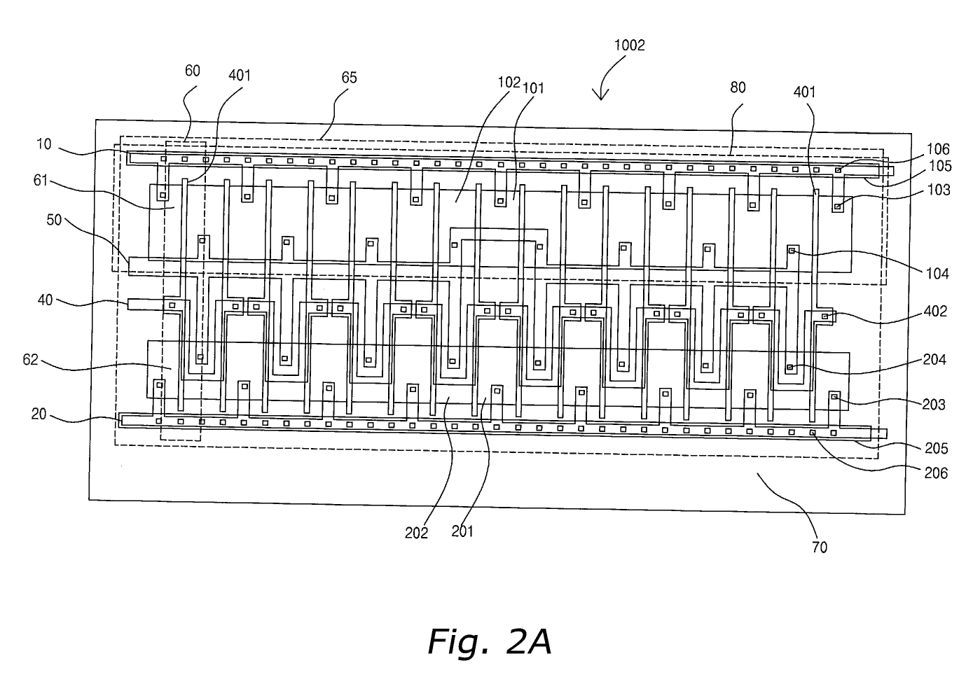

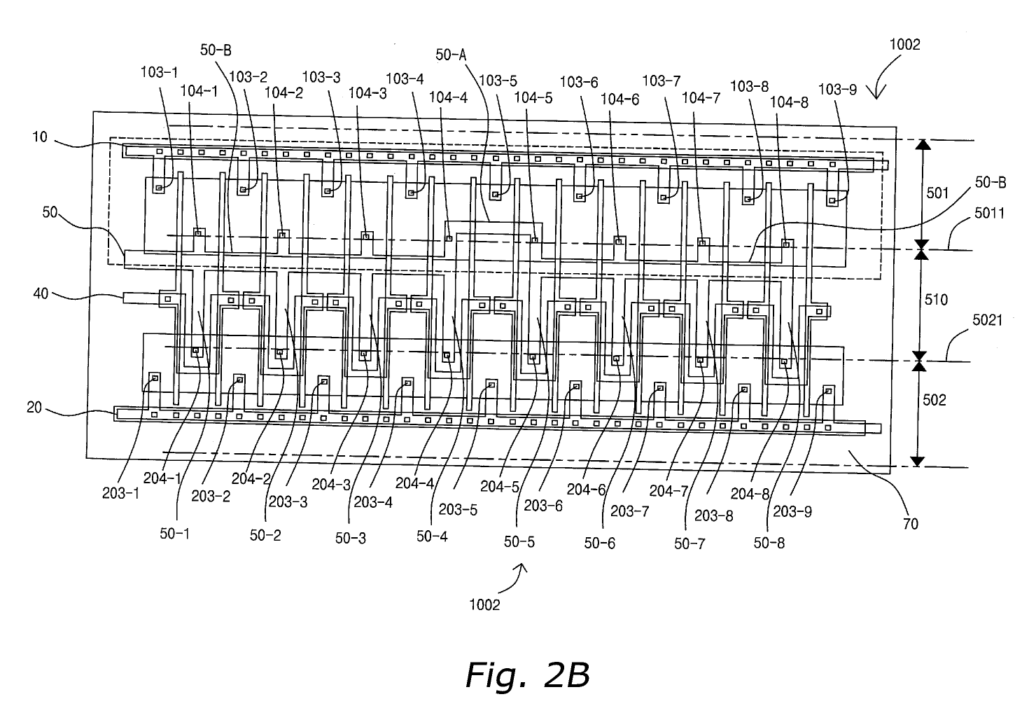

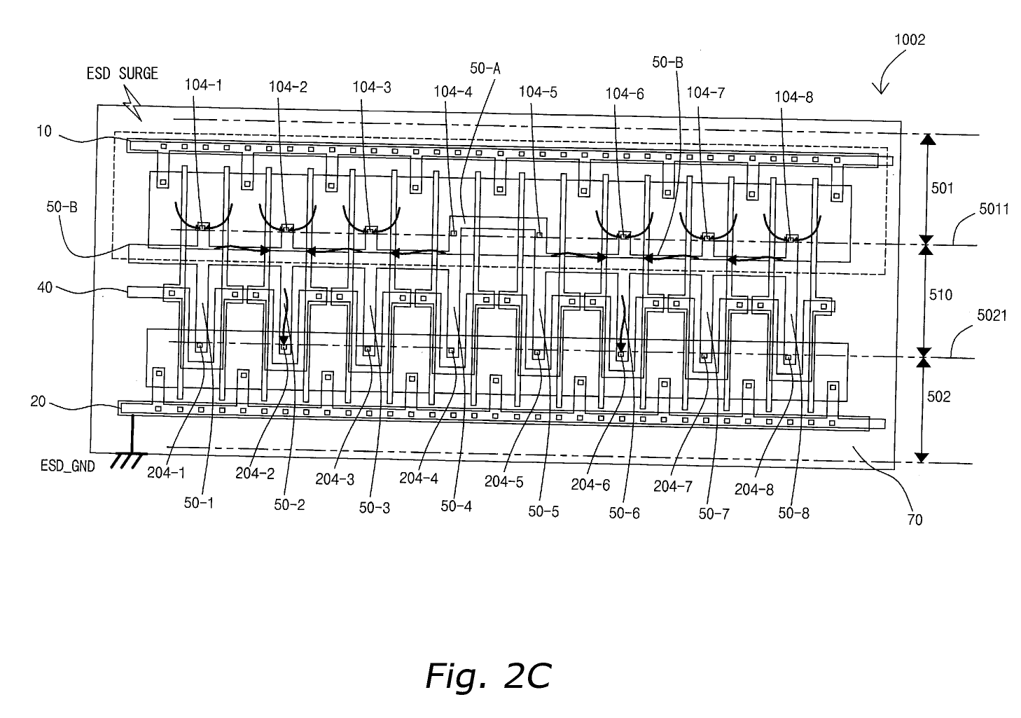

Referring now to FIGS. 2A to 2C, a semiconductor device according to a second embodiment will now be explained. In view of the similarity between the first and second embodiments, the parts of the second embodiment that are identical to the parts of the first embodiment will be given the same reference numerals as the parts of the first embodiment, except conductor 50. Moreover, the descriptions of the parts of the second embodiment that are identical to the parts of the first embodiment may be omitted for the sake of brevity. Semiconductor device 1002 according to the second embodiment is different from semiconductor device 1001 according to the first embodiment with respect to conductor 50.

FIG. 2A is a plan view of semiconductor device 1002 according to the second embodiment. FIG. 2B is a diagram for explaining the regions of semiconductor device 1002. FIG. 2C is a diagram for explaining the ESD current paths in semiconductor device 1002.

In the present embodiment, as shown in FIG. 2B, a conductor interconnecting conductor 50-1 to 50-8 is comprised of conductor 50-A disposed in region 501, and conductor 50-B disposed in region 5 10.

As shown in FIG. 2B, each one of the conductors 50-1 to 50-8 connects one of the drain contacts 104-1 to 104-8 and one of the drain contacts 204-1 to 204-8. Conductors 50-A and 50-B interconnect conductors 50-1 to 50-8.

Conductor 50-A connects conductor 50-4 and conductor 50-5 that are disposed in region 501, and more specifically, in the region that is not overlapped with drain contacts 104-4 and 104-5 on the farther side of NMOS transistors 62.

Conductor 50-B interconnects conductors 50-1 to 50-4, and interconnects conductors 50-5 to 50-8. Conductor 50-B is disposed, in region 510, on the NMOS transistors 62 side of drain contacts 104-1 to 104-4 of PMOS transistors 61. Similarly, conductor 50-B is disposed, in region 510, on the NMOS transistors 62 side of drain contacts 104-5 to 104-8 of PMOS transistors 61.

The operation of semiconductor device 1002 will now be described. If a positive surge enters conductor 10 during an ESD surge event, the surge current will be conducted to drain contacts 104 (104-1 to 104-8) by way of source contacts 103 (103-1 to 103-9), source regions 101, and drain regions 102 of PMOS transistors 61.

The surge current conducted to drain contacts 104 (104-1 to 104-4) is then conducted to each of the drain contacts 204 (204-1 to 204-4) of the paired NMOS transistors 62 by way of conductors 50-1 to 50-4 of conductor 50. The surge current conducted to drain contacts 104 (104-5 to 104-8) is then conducted to each of the drain contacts 204 (204-5 to 204-8) of the paired NMOS transistors 62 by way of conductors 50-5 to 50-8 of conductor 50.

Since conductor 50-4 and conductor 50-5 are connected through conductor 50-A on the conductor 10 side of drain contacts 104-4 and 104-5, surge current is not conducted between drain contacts 104-4 and 104-5 due to the electric field extending from drain contact 104-4 to drain contact 204-4 and the electric field extending from drain contact 104-5 to drain contact 204-5. As a result, the surge current is separated into two portions, that is, one current portion from drain contacts 104-1 to 104-4 and the other current portion from drain contacts 104-5 and 104-8. Therefore, the surge current conducted to one of the drain contacts 204 is limited to, at maximum, one half of the total surge current from drain contacts 104-1 to 104-8.

In the above mentioned second embodiment, drain contact 104-4 and drain contact 104-5 are connected by way of conductor 50-A. However, it will be appreciated by those skilled in the art that at least any two of the drain contacts 104-1 to 104-8, i.e., not limited to drain contact 104-4 and drain contact 104-5, may be connected by way of conductor 50-A. For example, drain contact 104-2 and drain contact 104-3 may be connected by way of conductor 50-A, while drain contact 104-5 and drain contact 104-6 may be connected by way of conductor 50-A. In this configuration where two conductors 50-A are provided, surge current will be separated into three portions.

As with the other preferable modification, three or more drain contacts 104 may be connected by way of conductor 50-A in region 501. In this configuration, surge current will be separated by both sides of conductor 50-A.

Preferable modifications described in the explanation of the first embodiment may be also applied to the second embodiment.

### Third Embodiment

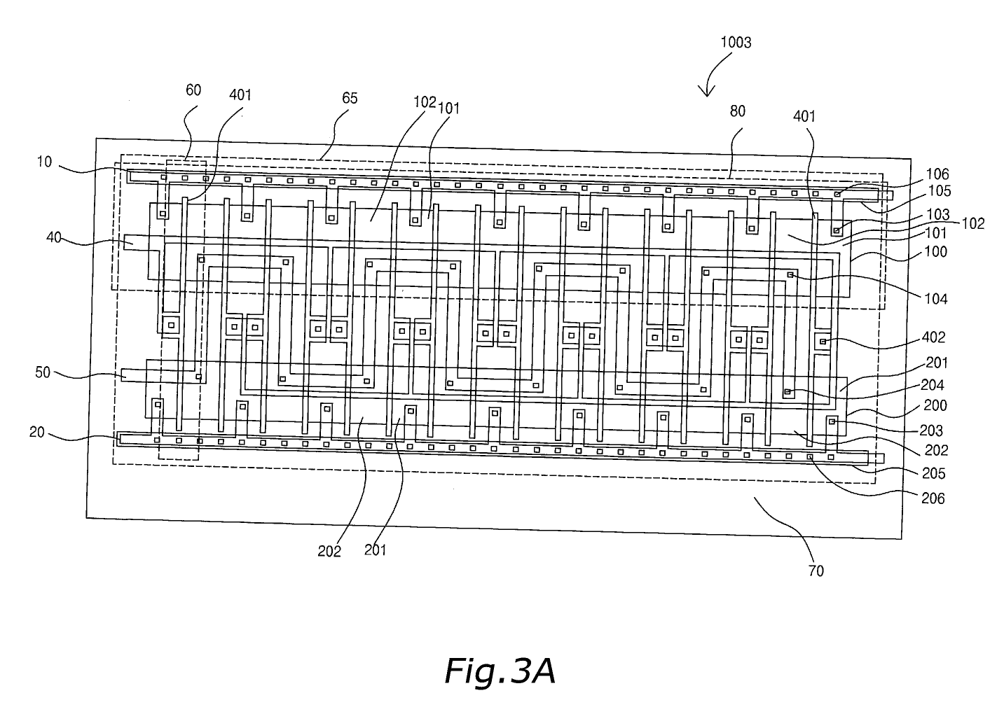

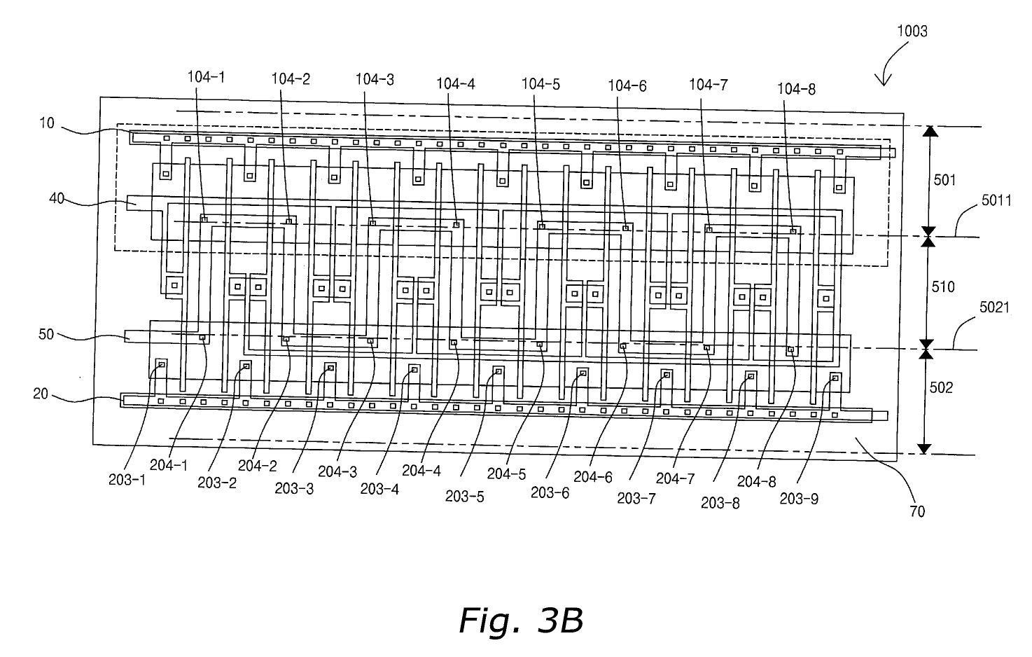

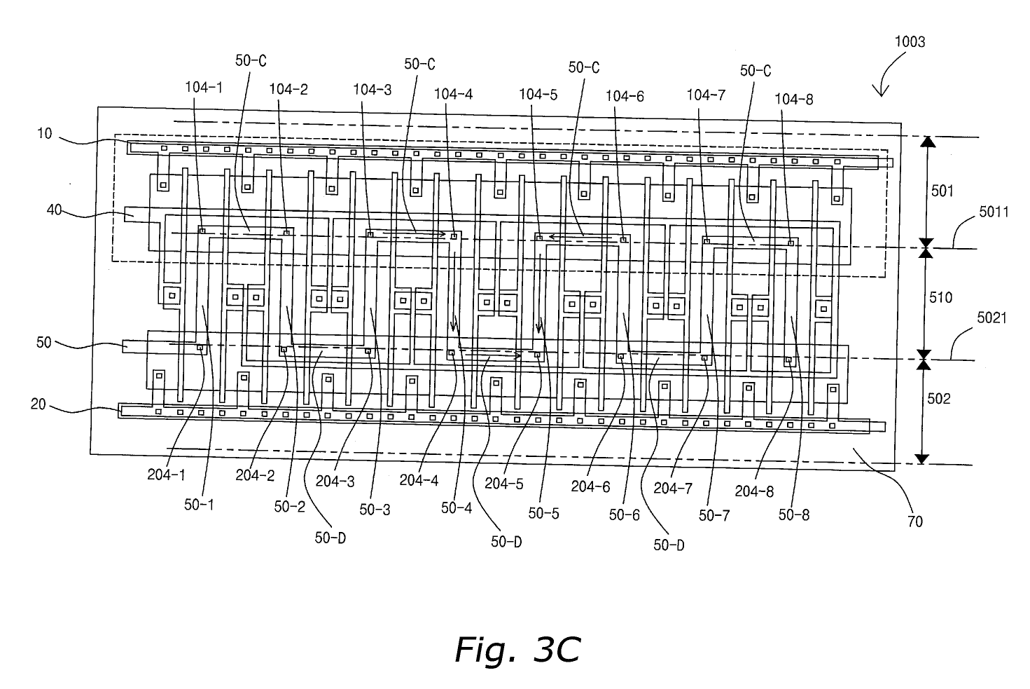

Referring now to FIG. 3A to 3C, a semiconductor device according to a third embodiment will now be explained. In view of the similarity between the first and third embodiments, the parts of the third embodiment that are identical to the parts of the first embodiment will be given the same reference numerals as the parts of the first embodiment, except conductor 40 and conductor 50. Moreover, the descriptions of the parts of the third embodiment that are identical to the parts of the first embodiment may be omitted for the sake of brevity. Semiconductor device 1003 according to the present embodiment is different from semiconductor device 1001 according to the first embodiment with respect to conductor 40 and conductor 50.

FIG. 3A is a plan view of semiconductor device 1003 according to the third embodiment. FIG. 3B is a diagram for explaining the regions of semiconductor device 1003. FIG. 3C is a diagram for explaining the ESD current paths in semiconductor device 1003.

In the present embodiment, conductor 50 is comprised of conductors 50-1 to 50-8, conductor 50-C, and conductor 50-D. Each one of the conductors 50-1 to 50-8 connects one of the drain contacts 104-1 to 104-8 and one of the drain contacts 204-1 to 204-8. Conductor 50-C and conductor 50-D interconnect conductors 50-1 to 50-8.

As shown in FIG. 3C, conductor 50-C respectively connects drain contact 104-1 and 104-2, drain contact 104-3 and 104-4, drain contact 104-5 and 104-6, and drain contact 105-7 and 106-8.

As shown in FIG. 3C, conductor 50-D respectively connects drain contact 204-2 and 204-3, drain contact 204-4 and 204-5, and drain contact 204-6 and 204-7.

As shown in FIG. 3C, each two adjacent conductors of the conductors 50-1 to 50-8 are alternately connected on the PMOS transistors 61 side and the NMOS transistors 62 side. For example, conductor 50-1 and 50-2 are connected by way of conductor 50-C. Conductor 50-2 and 50-3 are connected by way of conductor 50-D. Conductor 50-3 and 50-4 are connected by way of conductor 50-C. Conductor 50-C is disposed on boundary 5011 between region 501 and region 510, while conductor 50-D is disposed on boundary 5021 between region 510 and region 502.

Both conductor 50-C and conductor 50-D may be disposed in region 510. Thus, the semiconductor device according to the present embodiment has flexibility in the arrangement of the conductor 50-C and conductor 50-D.

The operation of semiconductor device 1003 will now be described. If a positive surge enters conductor 10 during an ESD surge event, the surge current will be conducted to drain contacts 104 (104-1 to 104-8) by way of source contacts (103-1 to 103-9), source regions 101, and drain regions 102 of PMOS transistors 61.

The surge current conducted to drain contacts 104 (104-1 to 104-8) is then conducted to each of the drain contacts 204 (204-1 to 204-8) of the paired NMOS transistors 62 by way of corresponding conductors 50-1 to 50-8.

In this operation, the surge current conducted to a specific drain contact of drain contacts 204 is limited to the surge current from four drain contacts 104 at most. The reason for this will be described below by using the surge current conducted to drain contact 204-5 as an example.

Surge current conducted from drain contact 104-2 to drain contact 204-5 is assumed to have a current path through drain contact 104-2, conductor 50-2, drain contact 204-2, conductor 50-D, drain contact 204-3, conductor 50-3, drain contact 104-3, conductor 50-C, drain contact 104-4, conductor 50-4, drain contact 204-4, conductor 50-D, and drain contact 204-5. However, a portion of the path at conductor 50-3 in the current path is directed from the NMOS transistors 62 side to the PMOS transistors 61 side, which is the opposite direction to the electric field that is generated. Thus, the surge current is actually not conducted as assumed above.

Similarly, the surge current conducted from drain contact 104-7 to drain contact 204-5 is assumed to have a current path through drain contact 104-7, conductor 50-7, drain contact 204-7, conductor 50-D, drain contact 204-6, conductor 50-6, drain contact 104-6, conductor 50-C, drain contact 104-5, conductor 50-5, and drain contact 204-5. However, a portion of the path at conductor 50-6 in the current path is directed from the NMOS transistors 62 side to the PMOS transistors 61 side, which is the opposite direction to the electric field that is generated. Thus, the surge current is not actually conducted as assumed above.

As a result, as explained above by using the surge current conducted to the drain contact 204-5 as an example, the surge current conducted to a specific drain contact of the drain contacts 204 is limited to the surge current from four drain contacts 104 at most. Therefore, the semiconductor device 1003 according to the present embodiment can be prevented from performance deterioration or breakage during an ESD surge event. Conductors 50-C and 50-D may not be necessarily disposed in region 501 or region 502, as opposed to conductor 50-0 or 50-A of semiconductor devices according to the first and second embodiments. In other words, conductor 50-C and conductor 50-D may be disposed in region 5 10. Thus, the semiconductor device 1003 according to the present embodiment has flexibility in the arrangement of the conductor 50-C and conductor 50-D.

The semiconductor device according to the present embodiment may be manufactured through a conventional CMOS manufacturing process with a slight change in conductor 50 in order to introduce conductor 50-C and conductor 50-D. No increase in the area for CMOS circuits is involved, as unoccupied regions for conductors may be used to implement the change in conductor 50.

The operation was described above in a situation in which a positive surge current is conducted from conductor 10. A similar explanation can be provided in a situation in which a negative surge current is conducted from conductor 20.

Preferable modifications described in the explanation for the first embodiment may be also applied to the third embodiment. For example, as described with reference to FIG. 1E, it is preferable that the line of the edges of conductor 50-C match boundary 5011 or are located on the conductor 10 side of boundary 5011. Similarly, it is preferable that the line of edges of conductor 50-D (the edges on the conductor 20 side) match boundary 5021 or are located on the conductor 20 side of boundary 5021.

### Fourth Embodiment

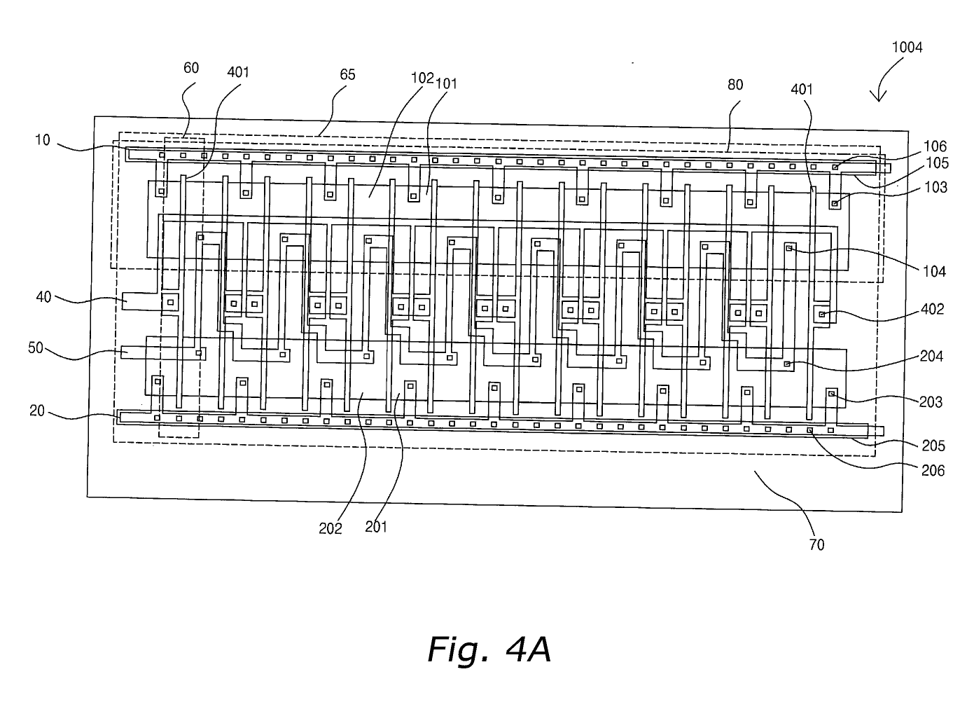

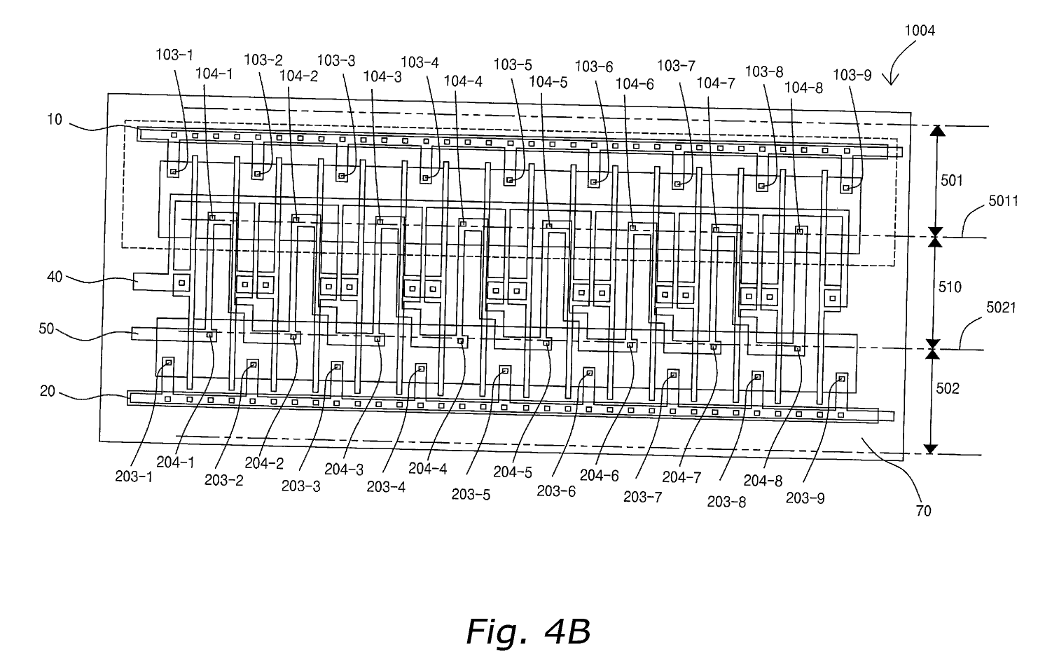

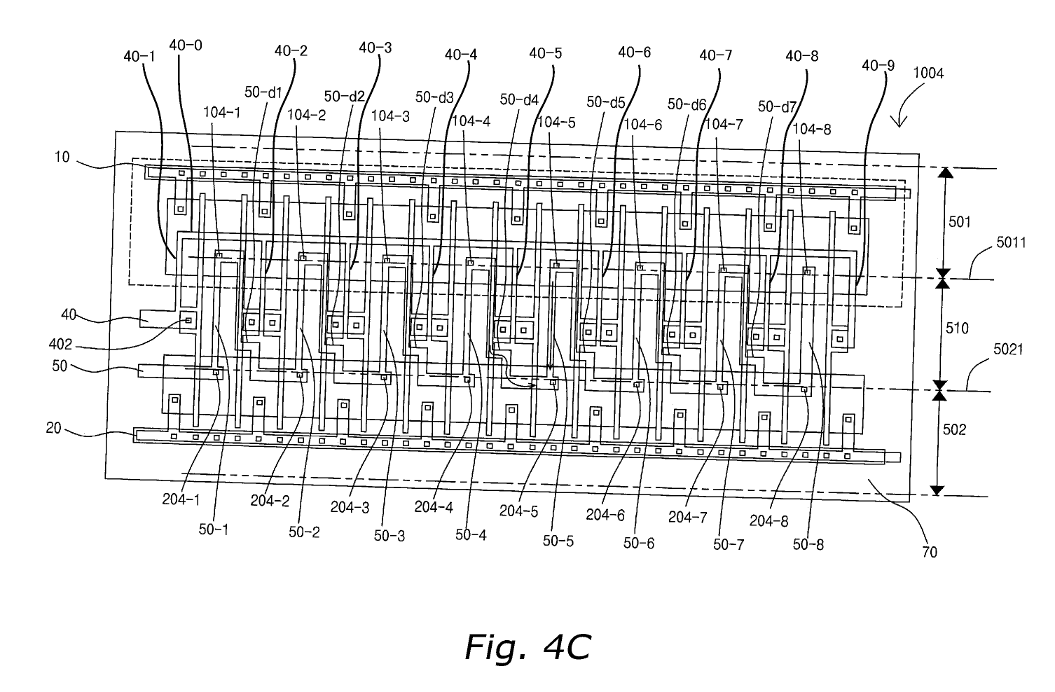

Referring now to FIG. 4A to 4C, a semiconductor device according to a fourth embodiment will now be explained. In view of the similarity between the first and fourth embodiments, the parts of the fourth embodiment that are identical to the parts of the first embodiment will be given the same reference numerals as the parts of the first embodiment, except conductor 40 and conductor 50. Moreover, the descriptions of the parts of the fourth embodiment that are identical to the parts of the first embodiment may be omitted for the sake of brevity. Semiconductor device 1004 according to the present embodiment is different from semiconductor device 1001 according to the first embodiment with respect to conductor 40 and conductor 50.

FIG. 4A is a plan view of semiconductor device 1004 according to the fourth embodiment. FIG. 4B is a diagram for explaining the regions of semiconductor device 1004. FIG. 4C is a diagram for explaining the ESD current paths in semiconductor device 1004.

In the present embodiment, as shown in FIG. 4A to 4C, conductor 50 is comprised of conductors 50-1 to 50-8 and conductors 50-d1 to 50-d7. Each one of the conductors 50-1 to 50-8 connects one of the drain contacts 104-1 to 104-8 with one of the drain contacts 204-1 to 204-8. Conductors 50-d1 to 50-d7 interconnect conductors 50-1 to 50-8. Each of the conductors 50-d1 to 50-d7 connects one of the drain contacts 104 of PMOS transistors 61 and an adjacent drain contact to one of the drain contacts 204. Specifically, conductors 50-d1 to 50-d7 respectively connect drain contacts 104-1 and 204-2, drain contacts 104-2 and 204-3, drain contacts 104-3 and 204-4, drain contacts 104-4 and 204-5, drain contacts 104-5 and 204-6, drain contacts 104-6 and 204-7, and drain contacts 104-7 and 204-8.

Each of the conductors 50-d1 to 50-d7 is disposed on the drain contact 204 side of an imaginary line with which two drain contacts on both ends of the conductor are connected. For example, conductor 50-d1 is disposed on the drain contact 204 side of an imaginary line with which drain contact 104-1 and drain contact 204-2 are connected, so as to detour gate contact 402 on the conductor 20 side.

Note that each of conductors 50-d1 to 50-d7 may be disposed on the drain contact 104 side of an imaginary line with which two drain contacts on both ends of the conductor are connected, so as to detour gate contact 402 on the conductor 10 side.

As shown in FIG. 4C, conductor 40 is comprised of conductor 40-0 and a plurality of conductors 40-1 to 40-9. Conductor 40-0 extends along conductor 10 in region 501. Conductors 40-1 to 40-9 extend from conductor 40-0 toward conductor 20, that is, from region 501 to region 510. Front ends of conductors 40-1 to 40-9 are connected with gate electrodes 401 by way of gate contacts 402.

The operation of semiconductor device 1004 will now be described. If a positive surge enters conductor 10 during an ESD surge event, the surge current is conducted to drain contacts 104 (104-1 to 104-8) by way of source contacts (103-1 to 103-9), source regions 101, and drain regions 102 of PMOS transistors 61.

The surge current conducted to drain contacts 104 (for example, drain contact 104-5) is then conducted to the paired drain contact (for example, drain contact 204-5) or to a drain contact (for example, drain contact 204-6) adjacent to the paired drain contact (for example, drain contact 204-5).

In this operation, the surge current conducted to a specific drain contact (for example, drain contact 204-5) of the drain contacts 204 is limited to surge current from the paired drain contact (for example, drain contact 104-5) and the surge current from the drain contact (for example, drain contact 104-4) adjacent to the paired drain contact. The reason for this will be described below by using surge current conducted to drain contact 204-5 as an example.

First, if a surge current path from drain contact 104-3 to drain contact 204-5 is assumed, a portion of the path of conductor 50-4 in the surge current path is directed opposite to the electric field from PMOS transistors 61 to NMOS transistors 62. Similarly, if a surge current path from drain contact 104-6 to drain contact 204-5 is assumed, a portion of the path of conductor 50-d5 in the surge current path is directed opposite to the electric field from PMOS transistors 61 to NMOS transistors 62. Thus, surge current will not be conducted as assumed above to drain contact 204-5 from drain contacts farther than drain contacts 104-4, 104-5.

As a result, as explained above by using surge current conducted to drain contact 204-5 as an example, the surge current conducted to a specific drain contact of drain contacts 204 is limited to the surge current from two of the drain contacts 104 at most. Therefore, the semiconductor device 1004 according to the present embodiment can be prevented from performance deterioration or breakage during an ESD surge event.

In the present embodiment, conductor 50-d may not be necessarily disposed in region 501, as opposed to the semiconductor devices according to the first and second embodiments. In other words, most of conductor 50 may be disposed in region 510. Thus, the semiconductor device has flexibility in the arrangement of conductor 50.

The semiconductor device according to the present embodiment may be manufactured through a conventional CMOS manufacturing process with a slight change in conductor 50. No increase in the area for CMOS circuits is involved, as unoccupied regions for conductors may be used to implement the change in conductor 50.

The operation was described above in a situation in which a positive surge current is conducted from conductor 10. A similar explanation can be provided in a situation in which negative surge current is conducted from conductor 20.

Preferable modifications described in the explanation for the first embodiment may be also applied to the fourth embodiment.

The term “configured” as used herein to describe a component, section or part of a device includes hardware and/or software that is constructed and/or programmed to carry out the desired function.

Moreover, terms that are expressed as “means-plus function” in the claims should include any structure that can be utilized to carry out the function of that part of the present invention.

The terms of degree such as “substantially”, “about” and “approximately” as used herein mean a reasonable amount of deviation of the modified term such that the end result is not significantly changed. For example, these terms can be construed as including a deviation of at least ±5% of the modified term if this deviation would not negate the meaning of the word it modifies.

This application claims priority to Japanese Patent Application No. 2005-207296. The entire disclosure of Japanese Patent Application No. 2005-207296 is hereby incorporated herein by reference.

While only selected embodiments have been chosen to illustrate the present invention, it will be apparent to those skilled in the art from this disclosure that various changes and modifications can be made herein without departing from the scope of the invention as defined in the appended claims. Furthermore, the foregoing descriptions of the embodiments according to the present invention are provided for illustration only, and not for the purpose of limiting the invention as defined by the appended claims and their equivalents. Thus, the scope of the invention is not limited to the disclosed embodiments.

What is claimed is:

1. A semiconductor device comprising:
a first conductor;
a second conductor disposed along the first conductor;
a plurality of first MOS transistors of a first conductivity type disposed on the first conductor side between the first and second conductor, each of the first MOS transistors comprising:
a first contact;
a second contact; and
a first control electrode disposed between the first contact and the second contact;
a plurality of second MOS transistors of a second conductivity type disposed on the second conductor side between the first and second conductor, each of the second MOS transistors comprising:
a third contact paired with the second contact;
a fourth contact; and
a second control electrode disposed between the third contact and the fourth contact, the plurality of second MOS transistors forming a plurality of CMOS circuits with the plurality of first MOS transistors; and
a third conductor connecting the plurality of the second contacts with the plurality of the third contacts, the third conductor comprising:
a plurality of fourth conductors, each connecting a second contact with the paired third contact; and
a fifth conductor interconnecting the plurality of fourth conductors.

2. A semiconductor device according to claim 1, wherein the fifth conductor is partially or wholly located in a first region defined on the first conductor side of the second contacts.

3. A semiconductor device according to claim 2, wherein the fifth conductor is not overlapped with the second contacts in the first region.

4. A semiconductor device according to claim 1, wherein the fifth conductor is located on the first conductor side of an imaginary line that is in contact with the edges of the second contacts.

5. A semiconductor device according to claim 1, wherein the fifth conductor is partially or wholly formed in a metal conductor layer that overlies the fourth conductor.

6. A semiconductor device according to claim 1, further comprising a plurality of sixth conductors connected to the first control electrodes and the second control electrodes, each sixth conductor partially surrounding the fourth conductor in a U-shape on the second conductor side.

7. A semiconductor device comprising:
a first conductor;
a second conductor disposed along the first conductor;
a plurality of first MOS transistors of a first conductivity type disposed on the first conductor side between the first and second conductor, each of the first MOS transistors comprising:
a first contact;
a second contact; and
a first control electrode disposed between the first contact and the second contact;
a plurality of second MOS transistors of a second conductivity type disposed on the second conductor side between the first and second conductor, each of the second MOS transistors comprising:
a third contact paired with the second contact;
a fourth contact; and
a second control electrode disposed between the third contact and the fourth contact, the plurality of second MOS transistors forming a plurality of CMOS circuits with the plurality of first MOS transistors; and
a third conductor connecting the plurality of the second contacts with the plurality of the third contacts, the third conductor comprising:
a plurality of fourth conductors, each connecting a second contact with the paired third contact;
a conductor or a plurality of fifth conductors interconnecting the plurality of fourth conductors at the second contacts; and
a conductor or a plurality of sixth conductors interconnecting the plurality of fourth conductors at the third contacts.

8. A semiconductor device according to claim 7, wherein the plurality of fifth conductors and the plurality of sixth conductors alternately interconnect the plurality of fourth conductors.

9. A semiconductor device according to claim 7, the fifth conductor is partially located in a first region defined on the first conductor side of the second contacts.

10. A semiconductor device according to claim 7, wherein the fifth conductor is partially or wholly formed in a metal conductor layer that overlies the fourth conductor.

11. A semiconductor device according to claim 7, the fifth conductor is located in a first region defined on the first conductor side of the second contacts.

12. A semiconductor device according to claim 11, the sixth conductor is located in a second region defined on the second conductor side of the third contacts.

13. A semiconductor device comprising:
a first conductor;
a second conductor disposed along the first conductor;
a plurality of first MOS transistors of a first conductivity type disposed on the first conductor side between the first and second conductor, each of the first MOS transistors comprising:
a first contact;
a second contact; and
a first control electrode disposed between the first contact and the second contact;
a plurality of second MOS transistors of a second conductivity type disposed on the second conductor side between the first and second conductor, each of the second MOS transistors comprising:
a third contact paired with the second contact;
a fourth contact; and
a second control electrode disposed between the third contact and the fourth contact, the plurality of second MOS transistors forming a plurality of CMOS circuits with the plurality of first MOS transistors; and
a third conductor connecting the plurality of the second contacts with the plurality of the third contacts, the third conductor comprising:
a plurality of fourth conductors, each connecting the second contact with the paired third contact; and
a plurality of fifth conductors, each connecting a second contact with a third contact adjacent to the paired third contact.

14. A semiconductor device according to claim 13, wherein each fifth conductor is disposed on either the second contact side or the third contact side of an imaginary line that connects the corresponding second and third contact.

15. A semiconductor device according to claim 13, wherein the plurality of fifth conductors are partially or wholly formed in a metal conductor layer that overlies the fourth conductor.
